(19) United States
(12) Patent Application Publication
(10) Pub. No.: US 2010/0220449 A1
(43) Pub. Date: Sep. 2, 2010

(54) CIRCUIT BOARD MODULE AND I/O PORT COLLECTION BOARD THEREOF

(76) Inventor: Yen-Po YU, Taipei (TW)

Correspondence Address: Muncy, Geissler, Olds & Lowe, PLLC, 4000 Legato Road, Suite 310, FAIRFAX, VA, 22033, US

(21) Appl. No.: 12/708,335

(22) Filed: Feb. 18, 2010

(30) Foreign Application Priority Data
Feb. 27, 2009 (TW) 098106592

(51) Int. Cl. H05K 1/18

(52) U.S. Cl. 361/748

(57) ABSTRACT

A circuit board module includes a circuit board and an I/O port collection board. The circuit board includes at least a first transmission interface. The I/O port collection board has a substrate, a plurality of I/O ports, a plurality of traces, and at least a second transmission interface. The I/O ports, the traces, and the second transmission interface are formed on the substrate. The I/O ports are electrically connected with the second transmission interface via the traces. The second transmission interface is connecting with the first transmission interface of the circuit board.

### CROSS REFERENCE TO RELATED APPLICATIONS

This Non-provisional application claims priority under 35 U.S.C. §119(a) on Patent Application No(s). 098106592 filed in Taiwan, Republic of China on Feb. 27, 2009, the entire contents of which are hereby incorporated by reference.

### BACKGROUND OF THE INVENTION

1. Field of Invention

The invention relates to a circuit board module and, more particularly, to a circuit board module having an input/output (I/O) port collection board.

2. Related Art

With the development of integrated circuit (IC) technology, more and more electronic components and traces are formed on a circuit board, and the integration becomes higher. Consequently, how to reasonably use or manage the space on circuit board becomes a big issue of the circuit board design.

Normally, a motherboard comprises a central processing unit (CPU), a north bridge chip, a south bridge chip, active electronic components, passive electronic components, input/output (I/O) ports, traces, and a plurality of interface card slots. The I/O port may includes universal serial bus (USB) interfaces, fire ware interfaces, COM ports, line print terminal (LPT) ports, PS/2 ports, video graphics array (VGA) ports, fan I/O ports, or hard disk I/O ports. A user may connect an electronic component such as a hard disk, a fan, a flat cable, or a mobile storage with the I/O port to make a linkage between the electronic component and the motherboard. The I/O port may be electrically connected with the north bridge chip or the south bridge chip via the traces on the motherboard, further electrically connected with the CPU.

However, the design for the motherboard has the following disadvantages. First, some over-high interface cards may be blocked during the installation, and therefore the I/O ports at periphery of the interface card slot cannot be used. Second, since the I/O port connects with the chip via the traces overlaid on the circuit board, and the traces occupy area of the circuit board, a usage efficiency of the circuit board may hard to be improved due to area occupation of the traces. Furthermore, the traces increase the layout complexity and size of the circuit board. This makes circuit boards presented difficult to be thinner and smaller.

### SUMMARY OF THE INVENTION

The invention provides a circuit board module and an I/O port collection board thereof, which integrated with a plurality of I/O ports on a single circuit board, to solve the above mentioned problem.

The circuit board module according to an embodiment of the invention includes a circuit board and an I/O port collection board. The circuit board has at least a first transmission interface. The I/O port collection board has a substrate, a plurality of I/O ports, a plurality of traces, and at least a second transmission interface. The I/O ports, the traces, and the second transmission interface are formed on the substrate. The I/O ports are electrically connected with the second transmission interface via the traces. The second transmission interface is connecting with the first transmission interface of the circuit board.

An I/O port collection board according to the invention is connecting with a circuit board. The circuit board has at least a first transmission interface. The I/O port collection board has a substrate, a plurality of I/O ports, at least a second transmission interface, and a plurality of traces. The I/O ports are formed on the substrate. The second transmission interface is connected with the substrate for communicating with the first transmission interface of the circuit board. The traces are formed on the substrate to make the I/O ports electrically connected with the second transmission interface.

To sum up, a circuit board module according to the invention has an I/O port collection board integrated with a plurality of I/O ports, and it is connecting with a first transmission interface of a circuit board via a second transmission interface. At least a part of the I/O ports originally disposed on the circuit board are associated on the I/O port collection board, and as a result, the originally occupied space for I/O ports or traces on the circuit board is saved. Thus, a size of the circuit board is reduced, and a layout structure on the circuit board is simplified. Furthermore, since the I/O ports are associated on the I/O port collection board, interference may be avoided and insertion or connection of interface cards to the circuit board is easier.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a circuit board module according to a first preferable embodiment of the invention, wherein an I/O port collection board is inserted in a circuit board;

FIG. 2 is a schematic diagram showing a circuit board module according to a second preferable embodiment of the invention, wherein a circuit board is connecting with the I/O port collection board via a flat cable;

FIG. 3 is a schematic diagram showing a circuit board module according to another preferable embodiment of the invention, wherein a circuit board is connecting with the I/O port collection board via the wireless transmission;

FIG. 4 is a schematic diagram showing an I/O port collection board according to a preferable embodiment of the invention; and

FIG. 5 is a schematic diagram showing a circuit board module having an integration chip according to a preferable embodiment of the invention.

### DETAILED DESCRIPTION OF THE INVENTION

A circuit board module and an I/O port collection board are illustrated hereinafter according to preferable embodiments of the invention.

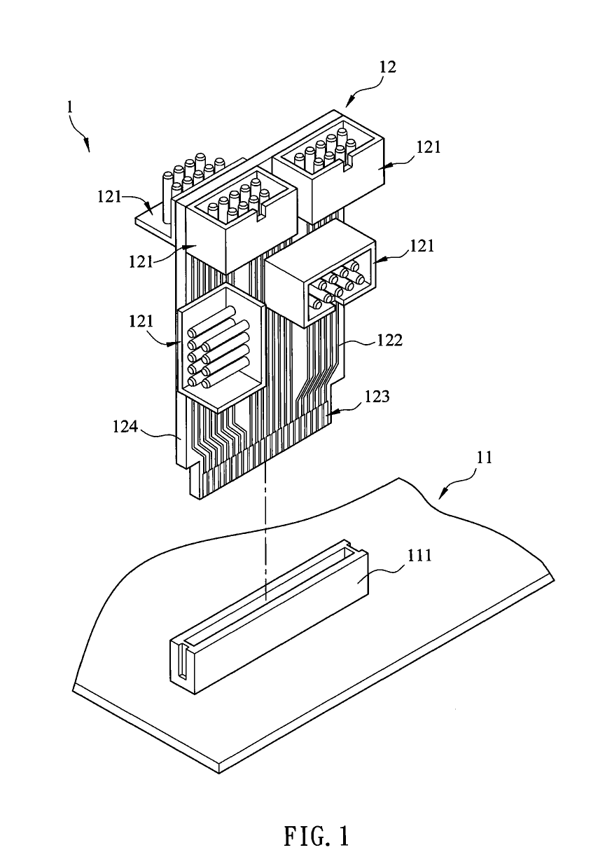

In FIG. 1, a circuit board module 1 according to a preferable embodiment of the invention includes a circuit board 11 and an I/O port collection board 12. The circuit board 11 has at least a first transmission interface 111. The type of the circuit board 11 is not limited in present invention, and the circuit board 11 may be a resin circuit board, a glass circuit board, a metal circuit board, a plastic circuit board, or one of other circuit boards with the first transmission interface 111. Additionally, the circuit board 11 may have essential functional electronic components according to its function. For example, in respect of the motherboard of the computer, the circuit board 11 may further have a CPU, a north bridge chip, a south bridge chip, an active electronic component, a passive electronic component, an I/O port and, traces formed thereon for connection.

The type of the first transmission interface 111 is not limited in present invention, and it may be a connector, an interface card slot, or a wireless transmission module. Types of said connector or interface card slot is not limited, may be a peripheral component interconnect (PCI) interface, a PCI-Express (PCI-E) interface, or one of other transmission interfaces. Also, means that said wireless transmission module uses is not limited, may be infrared ray, Bluetooth, ultra wide band (UWB), wireless USB, ZigBee, or laser transmission. If the wireless transmission is the radio transmission (such as the Bluetooth, the UWB, the wireless USB, or the ZigBee transmission), the first transmission interface 111 may include an antenna and a wireless signal processing unit. If the wireless transmission is the laser transmission, the first transmission interface 111 may include a photo diode and a photodetector. Additionally, the first transmission interface 111 is taken as an example in the embodiment of the invention, and the invention is not limited thereto. A plurality of first transmission interfaces may be disposed according a transmission requirement, and they may have different specification.

The I/O port collection board 12 has a substrate 124, a plurality of I/O ports 121, a plurality of traces 122, and at least a second transmission interface 123. The I/O ports 121, the traces 122, and the second transmission interface 123 are mounted on the substrate 124. The I/O ports 121 are electrically connected with the second transmission interface 123 via the traces 122. The second transmission interface 123 may be connecting with the first transmission interface 111 of the circuit board 11. The material of the substrate 124 of the I/O port collection board 12 is not limited in present invention, and it may include one or the combination of resin, glass, metal, and ceramics. Additionally, the traces 122 may be disposed on a surface or two opposite surfaces of the substrate 124. For example, when the I/O ports 121 are laid on the two opposite surfaces of the substrate 124, the traces 122 may be disposed on the two opposite surfaces of the substrate 124.

In this embodiment, the I/O ports 121 may be the I/O ports that originally disposed on the circuit board 11, or/and additionally added I/O ports. The I/O ports 121 may include the USB interface, the fire ware interface, the COM port, the LPT port, the PS/2 port, a video I/O port (such as an AV terminal or a S terminal of a video graphics array (VGA)), a fan I/O port, or a hard disk I/O port. The type of the I/O ports 121 is not limited, and various types of communication devices may be used as the I/O ports 121 as long as they can be utilized for transmitting a signal.

The type of the second transmission interface 123 is not limited in present invention, it may be a connector, a golden finger, or the wireless transmission module, and the second transmission interface 123 needs to cooperate with the first transmission interface 111 to be connecting with each other. The specification of the connector is not limited, may be a PCI, a PCI-E, or one of other transmission interfaces. The means that said wireless transmission module uses may be the infrared ray, the Bluetooth, UWB, wireless USB, ZigBee, or laser transmission. If the wireless transmission is the radio transmission (such as the Bluetooth, UWB, wireless USB, or ZigBee transmission), the second transmission interface 123 may include the antenna and the wireless signal processing unit. If the wireless transmission is the laser transmission, the second transmission interface 123 may include the photo diode and the photodetector. Additionally, the second transmission interface 123 is taken as an example in this embodiment, a plurality of second transmission interfaces may be disposed according the transmission requirement, and they may have different interface specifications.

In FIG. 1, in this embodiment, the first transmission interface 111 is, for example, an interface card slot in this embodiment, and the second transmission interface 123 is, for example, a golden finger, and the second transmission interface 123 is inserted in the first transmission interface 111 to be directly connecting with the first transmission interface 111. As a result, the I/O ports 121 of the I/O port collection board 12 can transmit the signal to the circuit board 11 via the traces 122, the second transmission interface 123, and the first transmission interface 111 to process the signal. For example, the signal is transmitted to the chip on the circuit board 11.

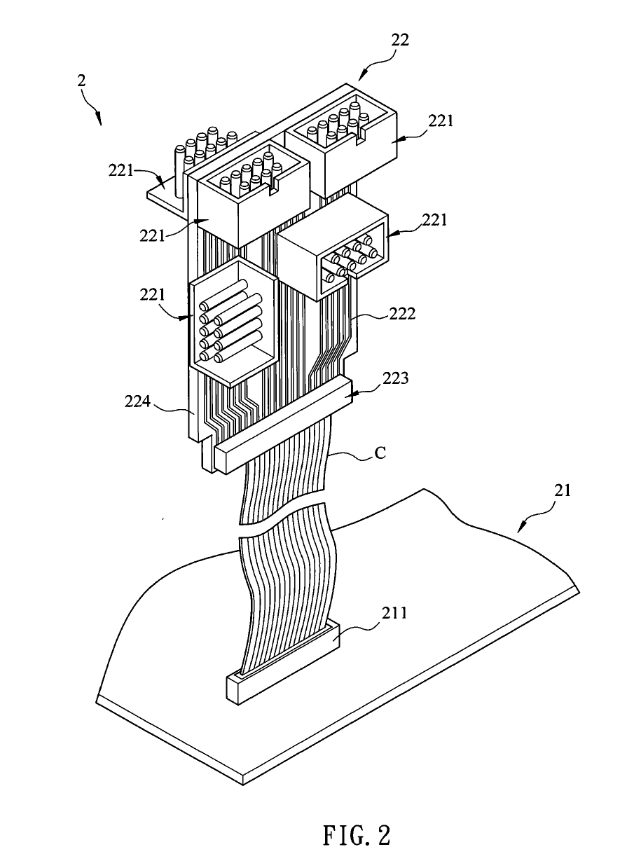

Besides abovementioned direct connection manner, the first transmission interface 111 may be connecting with the second transmission interface 123 via wire or wireless transmission. For example, as shown in FIG. 2, a circuit board module 2 includes a circuit board 21 and an I/O port collection board 22. The difference between the circuit board module 2 and the circuit board module 1 is that a first transmission interface 211 of the circuit board 21 and a second transmission interface 223 of an I/O port collection board 22 are connected with each other via a wire or a flat cable C. Surely, the first transmission interface 211, the second transmission interface 223 and the flat cable C are in corresponding specification. Additionally, via the flat cable C, the I/O port collection board 22 and the circuit board 21 may be disposed at different places. For example, the circuit board 21 may be disposed in a casing, and the I/O port collection board 22 may be disposed out of the casing to facilitate inserting the I/O ports 221 and dissipating heat of the I/O port collection board 22. Furthermore, the second transmission interface 223 in this embodiment also may be directly inserted in the first transmission interface 211.

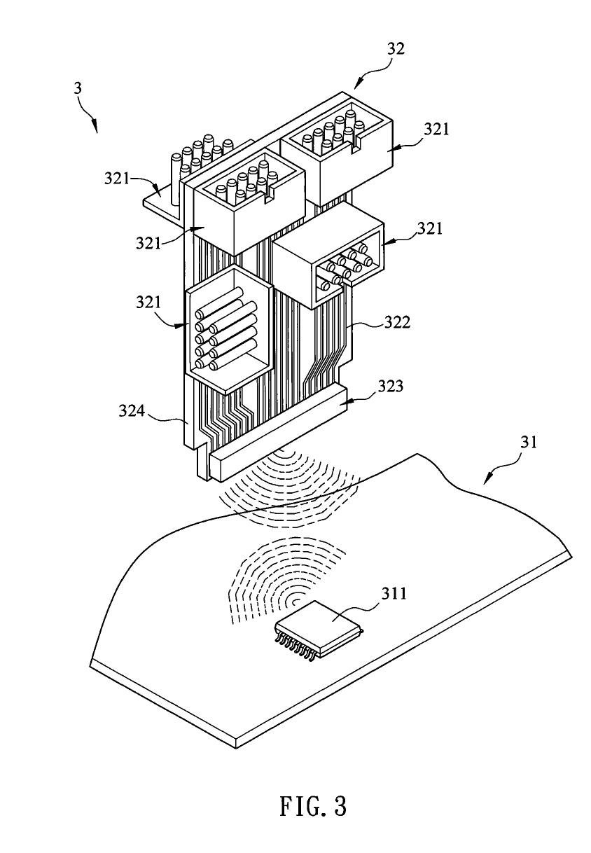

Additionally, as shown in FIG. 3, the circuit board module 3 includes a circuit board 31 and an I/O port collection board 32. The main difference between the circuit board module 3 and the circuit board module 1 and 2 is that the first transmission interface 311 and the second transmission interface 332 are via wireless transmission. The type of the wireless transmission is described above, and it is not described herein for a concise purpose. To be noted, said wire and wireless transmission can also be interactively used in present invention.

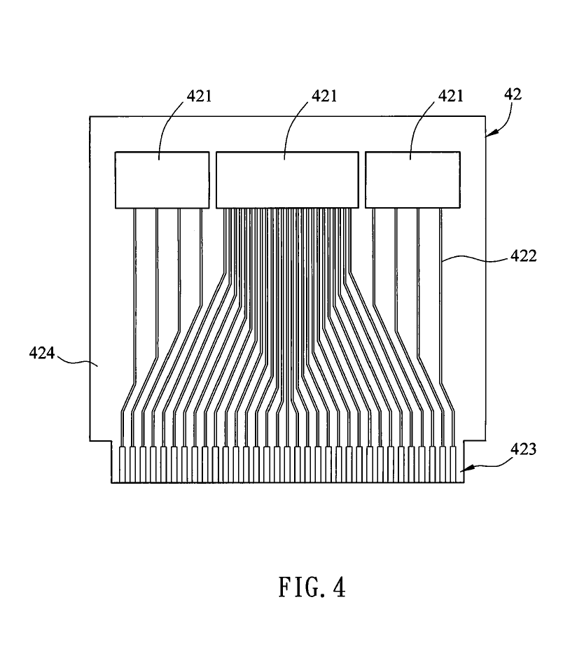

The electrical connection between the I/O port and the second transmission interface is illustrated hereinafter. In FIG. 4, the I/O port collection board 42 includes a plurality of I/O ports 421, a plurality of traces 422, and at least a second transmission interface 423. The I/O ports 421 are electrically connected with the second transmission interface 423 via the traces 422. Additionally, an end of each trace 422 is electrically connected with one I/O port 421, and the other end of each trace 422 is electrically connected with the second transmission interface 423. In this condition, the total number of pins of the I/O ports 421 is equal to the number of the traces 422. For example, when the I/O ports 421 have the USB interface (four pins), the LPT port (twenty-five pins), and the fire ware interface (four pins), the number of the traces 422 is thirty-three.

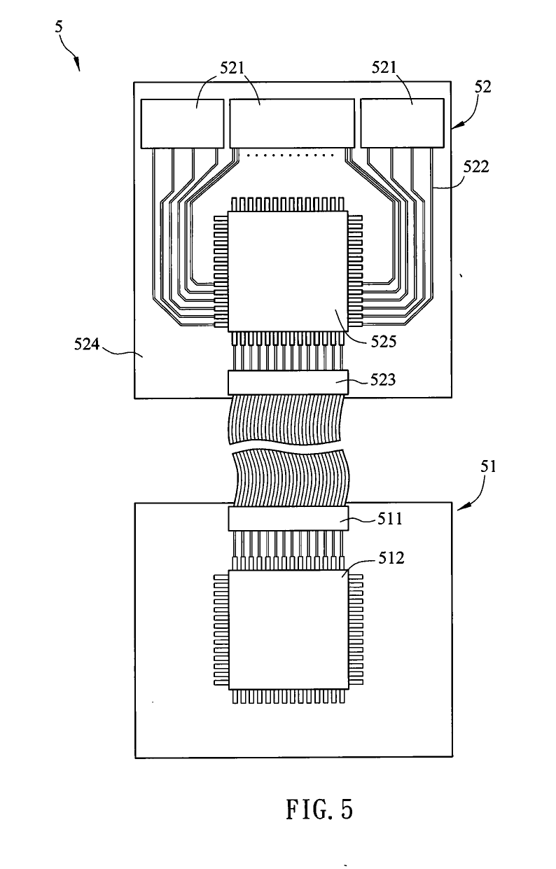

Additionally, as shown in FIG. 5, a circuit board module 5 includes a circuit board 51 and an I/O port collection board 52. Besides a plurality of I/O ports 521, a plurality of traces 522, and at least a second transmission interface 523, the I/O port collection board 52 further includes an integration chip 525. The integration chip 525 is electrically connected with the second transmission interface 523 and the I/O ports 521 via the traces 522. That is, the signal of the I/O ports 521 is transmitted to the integration chip 525 via the traces 522, and then it is transmitted to the second transmission interface 523 via the integration chip 525 and the traces 522. The integration chip 525 can integrate the signal to make the number of the traces between the integration chip 525 and the second transmission interface 523 smaller than the number of the traces between the integration chip 525 and the I/O ports 521.

Additionally, besides the first transmission interface 511, the circuit board 51 further includes at least a restoration chip 512. The restoration chip 512 is used for restoring the signals of the I/O ports 521 to facilitate the following processing. For example, when the I/O ports 521 include the USB interface, the fire ware interface, and the LPT port, the restoration chip 512 may restore the integration signal transmitted from the first transmission interface 511 to the USB interface signal, the fire ware interface signal, or the LPT port signal, and it transmits the signal to other signal processing units to perform following processing. The restoration chip 512 may exist alone, or it may be integrated with other functional chips. If the circuit board 51 is the motherboard of the computer, the restoration chip 512 may be integrated with the south bridge chip, which is not limited herein.

In sum up, a circuit board module according to the invention has an I/O port collection board integrated with a plurality of I/O ports. The I/O port collection board is connecting with a first transmission interface of a circuit board via a second transmission interface. As a result, at least a part of the I/O ports originally disposed on the circuit board are moved to the I/O port collection board, and the space originally for disposing the I/O ports and the traces on the circuit board is saved. Thus, the size of the circuit board is reduced to make the circuit board thinner, and a layout design on the circuit board is simplified. Furthermore, since the I/O ports are moved to the I/O port collection board, the interface card inserted on the circuit board is not interfered by the I/O port.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A circuit board module, comprising:
a circuit board having at least a first transmission interface; and
an input/output (I/O) port collection board having a substrate, a plurality of I/O ports, a plurality of traces, and at least a second transmission interface, wherein the I/O ports, the traces, and the second transmission interface are formed on the substrate, the I/O ports are electrically connected with the second transmission interface via the traces, and the second transmission interface is connecting with the first transmission interface of the circuit board.

2. The circuit board module according to claim 1, wherein an end of each of the traces is electrically connected with one of the I/O ports, respectively, and the other end of each of the traces is electrically connected with the second transmission interface.

3. The circuit board module according to claim 1, wherein the second transmission interface is connecting with the first transmission interface via a wire transmission.

4. The circuit board module according to claim 3, wherein the wire transmission is via a wire or a flat cable.

5. The circuit board module according to claim 1, wherein the second transmission interface is connecting with the first transmission interface via a wireless transmission.

6. The circuit board module according to claim 5, wherein the wireless transmission is via infrared ray, Bluetooth, wireless universal serial bus (USB), ultra-wideband (UWB), ZigBee, or laser transmission.

7. The circuit board module according to claim 1, wherein the second transmission interface is inserted in the first transmission interface for directly communicating with the first transmission interface.

8. The circuit board module according to claim 1, wherein the I/O port collection board further comprises an integration chip connected with the substrate and being electrically connected with the I/O ports and the second transmission interface via the traces.

9. The circuit board module according to claim 1, wherein the circuit board further comprises a restoration chip electrically connected with the first transmission interface.

10. An I/O port collection board for coupling with a circuit board having at least a first transmission interface, the I/O port collection board comprising:
a substrate;
a plurality of I/O ports formed on the substrate;
at least a second transmission interface connected with the substrate to be connecting with the first transmission interface of the circuit board; and
a plurality of traces formed on the substrate and electrically connecting the I/O port with the second transmission interface.

11. The I/O port collection board according to claim 10, wherein the second transmission interface is connecting with the first transmission interface via a wire transmission.

12. The I/O port collection board according to claim 11, wherein the wire transmission is via a wire or a flat cable.

13. The I/O port collection board according to claim 10, wherein the second transmission interface is connecting with the first transmission interface via a wireless transmission.

14. The I/O port collection board according to claim 13, wherein the wireless transmission is via infrared ray, Bluetooth, wireless USB, ultra-wideband (UWB), ZigBee, or laser transmission.

15. The I/O port collection board according to claim 10, wherein the second transmission interface is inserted in the first transmission interface for directly communicating with the first transmission interface.

16. The I/O port collection board according to claim 10, further comprising:
an integration chip connected with the substrate and being electrically connected with the I/O ports and the second transmission interface via the traces.
